(19) United States
(12) Patent Application Publication
(10) Pub. No.: US 2026/0117363 A1
(43) Pub. Date: Apr. 30, 2026

(54) CUTTING TOOL

(71) Applicant: Sumitomo Electric Industries, Ltd., Osaka-shi, Osaka (JP)

(72) Inventors: Haruyo FUKUI, Osaka-shi, Osaka (JP); Nozomi TSUKIHARA, Osaka-shi, Osaka (JP); Toshihiro TABATA, Osaka-shi, Osaka (JP); Hiroyoshi MOMIDA, Osaka-shi, Osaka (JP); Takahiro YAMASAKI, Osaka-shi, Osaka (JP)

(73) Assignee: Sumitomo Electric Industries, Ltd., Osaka-shi, Osaka (JP)

(21) Appl. No.: 19/135,127

(22) PCT Filed: Oct. 31, 2024
(86) PCT No.: PCT/JP2024/038910

§ 371 Date: Jun. 3, 2025

(51) Int. Cl. C23C 14/06; B23B 27/14; C23C 14/22; C23C 14/35

(52) U.S. Cl. CPC C23C 14/0641; B23B 27/148; B23B 2228/105; C23C 14/221; C23C 14/35

(57) ABSTRACT

A cutting tool, including: a base; and a coating disposed on the base, wherein the coating includes a first layer, the first layer is composed of an alternate layer in which a first unit layer and a second unit layer are alternately stacked, the first unit layer is composed of Ti_{1-a-b}AlₐSc_{b}N, the “a” represents 0.350 or more and 0.650 or less, the “b” represents 0.010 or more and 0.100 or less, the second unit layer is composed of Ti_{c}Si_{1-c}N, and the “c” represents 0.20 or more and 0.99 or less.

### TECHNICAL FIELD

The present disclosure relates to a cutting tool.

### BACKGROUND ART

A cutting tool comprising a base and a coating that coats the base has been conventionally used for cutting processing. For example, PTL 1 and PTL 2 disclose a cutting tool in which a base is coated with a coating formed by adding one or more elements selected from the group consisting of group 4 elements, group 5 elements, group 6 elements, Si, Y, and rare-earth elements into a nitride or a carbonitride that contains Ti and Al as main components.

### CITATION LIST

### Patent Literature

PTL 1: WO 1997/034023
PTL 2: Japanese Patent Laying-Open No. 2015-54995

### SUMMARY OF INVENTION

A cutting tool of the present disclosure is a cutting tool comprising: a base; and a coating disposed on the base, wherein the coating includes a first layer, the first layer is composed of an alternate layer in which a first unit layer and a second unit layer are alternately stacked, the first unit layer is composed of Ti_{1-a-b}AlₐSc_{b}N, the “a” represents 0.350 or more and 0.650 or less, the “b” represents 0.010 or more and 0.100 or less, the second unit layer is composed of Ti_{c}Si_{1-c}N, and the “c” represents 0.20 or more and 0.99 or less.

### BRIEF DESCRIPTION OF DRAWINGS

FIG. 1 is a schematic enlarged cross-sectional view of an example of a cutting tool according to Embodiment 1.

FIG. 2 is a schematic enlarged cross-sectional view of another example of the cutting tool according to Embodiment 1.

FIG. 3 is a schematic enlarged cross-sectional view of another example of the cutting tool according to Embodiment 1.

FIG. 4 is a schematic enlarged cross-sectional view of another example of the cutting tool according to Embodiment 1.

FIG. 5 is a view for describing an example of a ratio between thicknesses of a first unit layer and a second unit layer.

FIG. 6 is a schematic enlarged cross-sectional view of an example of a cutting tool according to Embodiment 2.

FIG. 7 is a schematic enlarged cross-sectional view of another example of the cutting tool according to Embodiment 2.

FIG. 8 is a schematic enlarged cross-sectional view of another example of the cutting tool according to Embodiment 2.

FIG. 9 is a schematic enlarged cross-sectional view of another example of the cutting tool according to Embodiment 2.

FIG. 10 is a view for describing an example of a ratio between thicknesses of a first unit layer and a third unit layer.

FIG. 11 is a schematic cross-sectional view of a cathode arc-ion plating apparatus used in Example.

FIG. 12 is a schematic top view of the cathode arc-ion plating apparatus illustrated in FIG. 11.

### DETAILED DESCRIPTION

### Problem to be Solved by the Present Disclosure

As a recent trend in the field of cutting processing, Sustainable Development Goals (SDGs) in order to achieve the sustainable and better world by 2030 has attracted more and more attention.

For cutting processing, a machine tool is used. Most of energy sources for operating the machine tool is electric power. To achieve the decarbonization, it is important to reduce energy during operation of the machine. It is reported that about 53% of the consumed energy of the machine tool is involved in a cutting oil (coolant). The cutting oil finally forms sludge that contains metal powder, and processed as industrial waste.

From the viewpoints of SDGs and environment conservation, dry processing without the cutting oil and improvement of processing efficiency have been required. In the dry processing and the high-efficiency processing, a temperature on a cutting edge becomes high during cutting.

Accordingly, an object of the present disclosure is to provide a cutting tool that can have an excellent tool lifetime particularly even under conditions such that a temperature on the cutting edge becomes high.

### Advantageous Effect of the Present Disclosure

According to the present disclosure, the cutting tool that can have an excellent tool lifetime particularly even under conditions such that a temperature on the cutting edge becomes high can be provided.

### DESCRIPTION OF EMBODIMENTS

First, aspects of the present disclosure will be listed and described.
(1) A cutting tool of the present disclosure is a cutting tool comprising: a base; and a coating disposed on the base, wherein the coating includes a first layer, the first layer is composed of an alternate layer in which a first unit layer and a second unit layer are alternately stacked, the first unit layer is composed of Ti_{1-a-b}AlₐSc_{b}N, the “a” represents 0.350 or more and 0.650 or less, the “b” represents 0.010 or more and 0.100 or less, the second unit layer is composed of Ti_{c}Si_{1-c}N, and the “c” represents 0.20 or more and 0.99 or less.

According to the present disclosure, the cutting tool that can have an excellent tool lifetime particularly even under conditions such that a temperature on the cutting edge becomes high can be provided. The reason is presumed as follows.

Sc in Ti_{1-a-b}AlₐSc_{b}N of the first unit layer is oxidized under the cutting conditions at high temperature to generate a passivated form composed of Sc₂O₃ in the coating. Since Sc₂O₃ has an extremely high melting point of 2485° C., the passivated form composed of Sc₂O₃ can be stably present even under the cutting conditions at high temperature. Thus, stability of performance of the cutting tool is improved even under the cutting conditions at high temperature.

Sc₂O₃ yields a so-called “keying on effect”, which is precipitation on a crystal particle boundary of TiAlScN, and therefore it is protected that oxygen permeates the crystal particle boundary from the coating surface to be diffused inward the coating. The keying on effect remarkably improves oxidation resistance of the coating. Further, reactivity between a workpiece and the coating can be inhibited by the keying on effect to reduce a frictional coefficient between the workpiece and the coating.

A lattice constant of ScN is 4.51 Å, which is larger than a lattice constant of TiN, 4.23 Å, and a lattice constant of AlN, 4.12 Å. Thus, the presence of Sc in the first unit layer introduces strain in the first unit layer to allow structure of the first unit layer to be fine. This increases hardness of the first unit layer to improve wear resistance of the coating that includes the first layer.

PTL 1 and PTL 2 disclose a coating in which yttrium is added into a nitride or a carbonitride that contain Ti and Al as main components (hereinafter, also referred to as “TiAlN or TiAlCN”). However, a lattice constant of YN is as large as 4.88 Å, and thereby an amount at which a solid solution can be formed in TiAlN or TiAlCN is limited. Thus, TiAlN or TiAlCN in which yttrium is added has an insufficient introducing amount of the strain, and the effects of increasing hardness and improving wear resistance of the coating are insufficient.

Ti_{1-a-b}AlₐSc_{b}N in the first unit layer has excellent heat resistance compared with Ti_{c}Si_{1-c}N in the second unit layer. Therefore, thermal wear of the first unit layer is inhibited even at high temperature, and the first layer can retain the excellent wear resistance.

It is presumed that Ti_{c}Si_{1-c}N in the second unit layer has a so-called nanocomposite structure in which nanometer-sized cubic TiN crystals and amorphous SiNₓ are mixed. Since having extremely increased hardness, the second unit layer that has the nanocomposite structure has an excellent balance between wear resistance, heat-shielding resistance, oxidation resistance, and toughness. Thus, the first layer that includes the second unit layer contributes to lengthening of the lifetime of the cutting tool.

Ti_{c}Si_{1-c}N in the second unit layer has a large compressive residual stress compared with Ti_{1-a-b}AlₐSc_{b}N in the first unit layer, and contributes to improvement of chipping resistance of the first layer.

In some alloy tool steels of one example of the workpiece, another alloy element such as Cr is added. When the coating contains Cr, the coating and a component in the workpiece are mutually diffused during cutting processing to enhance wear, and thereby the coating preferably not contains Cr. In the cutting tool of Embodiment 1, the first layer contains no Cr, and thus, the wear due to the mutual diffusion between the coating and the component in the workpiece that contains Cris inhibited.

The first layer is composed of an alternate layer in which the first unit layer and the second unit layer are alternately stacked. Therefore, even under cutting conditions at high temperature, the first layer can have both of: the effect of improving stability, oxidation resistance, heat resistance, and wear resistance of the coating, and the effect of reducing the frictional coefficient due to the first unit layer; and the effect of improving wear resistance, heat-shielding resistance, chipping resistance, and oxidation resistance of the coating due to the second unit layer.

The first layer is composed of the alternate layer in which the first unit layer and the second unit layer are alternately stacked. On an interface between the first unit layer and the second unit layer, the composition and the crystal lattices are discontinuous. Thus, when cracking occurs from a surface of the coating during cutting, development of the cracking can be inhibited on the interface. The coating that includes the first layer inhibits chipping and breakage.

Because of the above reasons, the cutting tool that includes the first layer composed of the alternate layer in which the first unit layer and the second unit layer are alternately stacked can have an excellent tool lifetime particularly even under conditions such that a temperature on the cutting edge becomes high.
(2) According to the (1), between the first unit layer and the second unit layer adjacent to the first unit layer, a ratio λ1/λ2 of a thickness λ1 of the first unit layer to a thickness λ2 of the second unit layer may be 1 or more and 5 or less.

The first unit layer has high oxidation resistance, and also has excellent heat resistance compared with the second unit layer. When λ1/λ2 is 1 or more and 5 or less, the proportion of the first unit layer in the first layer increases to further improve the oxidation resistance and the heat resistance of the first layer. Thus, wear of the coating hardly occurs particularly even under conditions such that a temperature on the cutting edge becomes high, and further improves the tool lifetime of the cutting tool.

Further, when λ1/λ2 is 1 or more, wear resistance of the coating is improved. On the other hand, when λ1/λ2 is 5 or less, the effect of inhibiting development of cracking by stacking the first unit layer and the second unit layer tends to be easily obtained.
(3) According to the (1) or (2), an average thickness of the first unit layer may be 2 nm or more and 200 nm or less, and an average thickness of the second unit layer may be 2 nm or more and 200 nm or less. Thus the effect of inhibiting development of cracking that occurs on the surface of the coating is further improved.
(4) According to any one of the (1) to (3), the coating may further include a second layer disposed between the base and the first layer, a composition of the second layer may be same as a composition of any one unit layer of the first unit layer and the second unit layer, a thickness of the second layer may be larger than an average thickness of the unit layer that has the same composition, and the thickness of the second layer may be 0.1 μm or more and 1.0 μm or less. This can increase adhesiveness between the base and the coating.
(5) According to any one of the (1) to (4), the coating may further include a third layer provided on a side opposite to the base of the first layer, the third layer may be composed of TiCN or TiAlScCN, and a thickness of the third layer may be 0.1 μm or more and 1.0 μm or less.

A carbonitride typically tends to have a low frictional coefficient against a workpiece compared with a nitride. Such reduction in the frictional coefficient is presumably derived from contribution of the carbon atoms. The coating that includes the third layer reduces the frictional coefficient of the coating against the workpiece to further lengthen the lifetime of the cutting tool.
(6) According to any one of the (1) to (5), a thickness of the first layer may be 0.5 μm or more and 15 μm or less. The first layer that has a thickness of 0.5 μm or more easily yields the effect of improving hardness, wear resistance, heat resistance, oxidation resistance, and chipping resistance of the first layer to further lengthen the lifetime of the cutting tool. The first layer that has a thickness of 15 μm or less easily and stably exhibits chipping resistance.
(7) A cutting tool of the present disclosure is a cutting tool comprising: a base; and a coating disposed on the base, wherein the coating includes an A layer, the A layer is composed of an alternate layer in which a first unit layer and a third unit layer are alternately stacked, the first unit layer is composed of Ti_{1-a-b}AlₐSc_{b}N, the “a” represents 0.350 or more and 0.650 or less, the “b” represents 0.010 or more and 0.100 or less, the third unit layer is composed of Ti_{d}Si_{1-d-e}BₑN, the “d” represents 0.20 or more and 0.99 or less, and the “e” represents more than 0 and 0.05 or less.

According to the present disclosure, the cutting tool that can have an excellent tool lifetime particularly even under conditions such that a temperature on the cutting edge becomes high can be provided. The reason is presumably the same as the reason described in the (1). In the present disclosure, the following reason is further presumed.

In Ti_{d}Si_{1-d-e}BₑN in the third unit layer, boron increases hardness of the third unit layer and thereby increase hardness of the entire coating. In addition, since having a low melting point, an oxide of boron formed in cutting serves as a lubricant during cutting, and can inhibit agglutination of a workpiece on the cutting tool.
(8) According to the (7), between the first unit layer and the third unit layer adjacent to the first unit layer, a ratio λ1/λ3 of a thickness λ1 of the first unit layer to a thickness λ3 of the third unit layer may be 1 or more and 5 or less.

This further improves heat resistance and oxidation resistance of the A layer for the reason same as in the (2), and further improves the tool lifetime of the cutting tool.
(9) According to the (7) or (8), an average thickness of the first unit layer may be 2 nm or more and 200 nm or less, and an average thickness of the third unit layer may be 2 nm or more and 200 nm or less. This further improves the effect of inhibiting development of cracking that occurs on the surface of the coating.
(10) According to any one of the (7) to (9), the coating may further include a B layer disposed between the base and the A layer, and a composition of the B layer may be same as a composition of any one unit layer of the first unit layer and the third unit layer, a thickness of the B layer may be larger than an average thickness of the unit layer that has the same composition, and the thickness of the B layer may be 0.1 μm or more and 1 μm or less. This can increase adhesiveness between the base and the coating.
(11) According to any one of the (7) to (10), the coating may further include a C layer provided on a side opposite to the base of the A layer, the C layer may be composed of TiCN or TiAlScCN, and a thickness of the C layer may be 0.1 μm or more and 1.0 μm or less. This reduces a frictional coefficient of the coating against a workpiece to further lengthen the lifetime of the cutting tool.
(12) According to any one of the (7) to (111), a thickness of the A layer may be 0.5 μm or more and 15 μm or less. The A layer that has a thickness of 0.5 μm or more easily yields the effect of improving hardness, wear resistance, heat resistance, oxidation resistance, and chipping resistance of the A layer to further lengthen the lifetime of the cutting tool. The A layer that has a thickness of 15 μm or less easily and stably exhibits chipping resistance.

### DETAILED DESCRIPTION OF EMBODIMENTS

With reference to the drawings, specific examples of the cutting tool of the present disclosure will be described hereinafter. In the drawings of the present disclosure, a same reference sign represents same parts or corresponding parts. Dimensions such as length, width, thickness, and depth are appropriately modified to clarify and simplify the drawings, and do not always represent actual dimensions.

A description of a form “A to B” herein means A or more and B or less. When A has no description of a unit and only B has a description of a unit, the unit of A and the unit of B are same.

When a compound and the like are represented by a chemical formula herein, any conventionally known atomic ratios are included unless the atomic ratio is particularly limited, and should not be necessarily limited to only an atomic ratio within a stoichiometric range.

When one or more values are each described herein as lower limits and upper limits of numerical ranges, combinations of any one value described as the lower limit and any one value described as the upper limit are also disclosed.

Herein, “comprise”, “include”, “have”, and their conjugations are open-end terms. The open-end terms may further include an additional constituent in addition to an essential constituent, or may not include an additional constituent. The phrase “consist of” is a closed term. Note that, even when a configuration is expressed with the closed term, the configuration can include a normally associated impurity or an additional constituent that is unrelated to a subject technology.

### Embodiment 1: Cutting Tool (1)

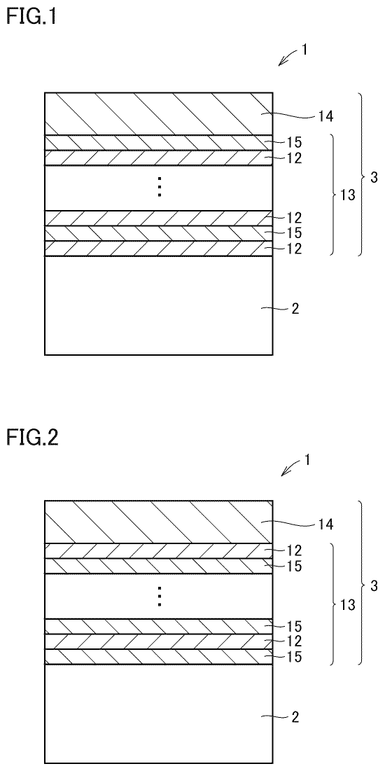

The cutting tool according to an embodiment of the present disclosure (hereinafter, also referred to as “Embodiment 1”) will be described by using FIG. 1 to FIG. 5. A cutting tool 1 of Embodiment 1 is cutting tool 1 comprising: a base 2; and a coating 3 disposed on base 2. Coating 3 includes a first layer 13. First layer 13 is composed of an alternate layer in which a first unit layer 12 and a second unit layer 15 are alternately stacked. First unit layer 12 is composed of Ti_{1-a-b}AlₐSc_{b}N. Here, “a” represents 0.350 or more and 0.650 or less, and “b” represents 0.010 or more and 0.100 or less. Second unit layer 15 is composed of Ti_{c}Si_{1-c}N. Here, “c” represents 0.20 or more and 0.99 or less.

### <<Cutting Tool>>

The cutting tool of Embodiment 1 can be suitably used as a drill, an endmill, an indexable cutting insert for a drill, an indexable cutting insert for an endmill, an indexable cutting insert for milling, an indexable cutting insert for turning, a metal saw, a gear-cutting tool, a reamer, a tap, and the like.

### <Base>

Any conventionally known composition of the base may be used. For example, any one of cemented carbide (such as WC-based cemented carbide, cemented carbide that contains WC and Co, and cemented carbide in which a carbonitride of Ti, Ta, Nb, or the like is further added), cermet (that contains TiC, TiN, TiCN, or the like as a main component), high-speed steel, ceramics (such as titanium carbide, silicon carbide, silicon nitride, aluminum nitride, and aluminum oxide), a cubic boron nitride sintered material, or a diamond sintered material may be used.

The composition of the base may be WC-based cemented carbide or cermet (particularly, TiCN-based cermet) from the viewpoint of excellent balance between hardness and strength at high temperature. The base composed of the WC-based cemented carbide or the cermet can contribute to lengthening of the lifetime of the cutting tool.

### <Coating>

In the cutting tool of Embodiment 1, the coating can coat at least a part involved in cutting of the base. The part involved in cutting of the base means, for example, a region where a distance from an edge ridgeline is 100 μm or less on the surface of the base. The coating may coat an entire surface of the base, or may coat an entire surface of the part involved in cutting of the base. As long as the effect exhibited by the cutting tool of the present disclosure is not impaired, a case where the coating is partially not formed on the part involved in cutting of the base does not depart from the scope of Embodiment 1. As long as the effect exhibited by the cutting tool of the present disclosure is not impaired, a case where the configuration of the coating is partially different does not depart from the scope of Embodiment 1.

As illustrated in FIG. 1 and FIG. 2, coating 3 includes first layer 13, and first layer 13 may be provided directly on base 2.

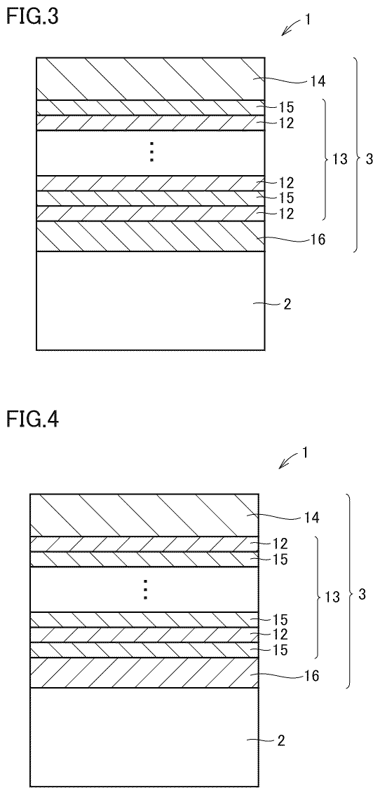

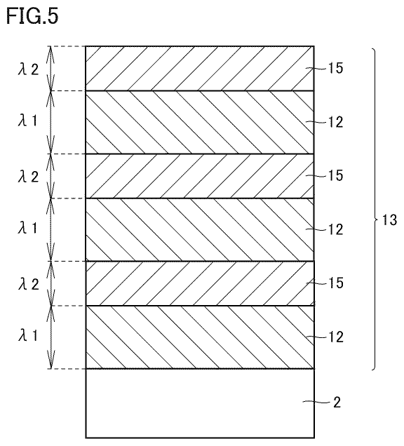

Coating 3 may include another layer in addition to first layer 13. As illustrated in FIG. 3 to FIG. 4, coating 3 may include a second layer 16 disposed between base 2 and first layer 13. As illustrated in FIG. 1 to FIG. 4, coating 3 may include a third layer 14 provided on a side opposite to base 2 of first layer 13.

A thickness of the coating may be 0.5 μm or more and 25 μm or less, may be 1.0 μm or more and 23 μm or less, or may be 5.0 μm or more and 20 μm or less.

The thickness of the coating is measured by observing a cross section of the coating using a scanning electron microscope (SEM). Specifically, an observation magnification of the sectional sample is set to 5000 to 10000, an observation area is set to 100 to 500 μm², and thickness widths are measured at three positions in one field to specify an average value thereof as the thickness of the coating. A thickness of each layer, described later, is similarly measured unless specific description.

A compressive residual stress of the coating may be 6 GPa or less in an absolute value. The compressive residual stress of the coating is a kind of internal stress (specific strain) present in the entire coating, and refers to a stress represented by a “-” (negative) value (unit: “GPa” is used in the present embodiment). Thus, a concept of a large compressive residual stress represents a large absolute value of the value, and a concept of a small compressive residual stress represents a small absolute value of the value. That is, the absolute vale of the compressive residual stress of 6 GPa or less means that a preferable compressive residual stress about the coating is −6 GPa or more and 0 GPa or less.

If the compressive residual stress of the coating is more than 0 GPa, which is tensile stress, it tends to be difficult to inhibit development of cracking generated from the outermost surface of the coating. On the other hand, if the absolute value of the compressive residual stress is more than 6 GPa, the stress may be large enough to peel the coating particularly from an edge portion of the cutting tool before the beginning of the cutting and thereby shorten the lifetime of the cutting tool.

The compressive residual stress of the coating can be measured by a sin 2ψ method using an X-ray residual stress apparatus (see “X-Ray Stress Measurement” (The Society of Materials Science, Japan, published in 1981 by Yokendo Ltd. Publishers) pp. 54 to 66).

The crystal structure of the coating may be cubic. When the crystal structure of the coating is cubic, the hardness of the coating increases. Each of the crystal structure of each layer in the coating may also be cubic. The crystal structure of the coating and each layer in the coating can be analyzed with an X-ray diffraction apparatus known in the field.

The hardness of the coating may be 30 GPa or more and 55 GPa or less, or may be 35 GPa or more and 50 GPa or less. According to this, the coating has sufficient hardness. The hardness of the entire coating can be measured by a nano-indenter method (Nano Indenter XP, manufactured by MTS Systems Corporation). Specifically, the measurement is performed by a method in accordance with ISO14577, the measurement load is 10 mN (1 gf), hardness on the surface of the coating is measured at three positions, and an average value thereof is specified as the “hardness”.

### <First Layer>

In the cutting tool of Embodiment 1, the first layer is composed of an alternate layer in which a first unit layer and a second unit layer are alternately stacked. The first layer composed of the alternate layer in which the first unit layer and the second unit layer are alternately stacked can be confirmed by difference in contrast by observing a flake sample that contains a cross section of the coating with a transmission electron microscope (TEM).

Any of the first unit layer and the second unit layer may be disposed at a position closest to the side of the base. Any of first unit layer 12 and second unit layer 15 may be disposed at a position closest to the surface side of coating 3.

A thickness of the first layer may be 0.5 μm or more and 15 μm or less, may be 2 μm or more and 15 μm or less, or may be 5 μm or more and 10 μm or less.

The thickness of the first layer can be measured by observing the cross section of the coating using a transmission electron microscope (TEM). The cutting tool is cut in a direction along a normal line of the surface of the coating to prepare a flake sample that contains the cross section. The flake sample is observed with a TEM. The observation magnification is 20,000 to 5,000,000, and the measurement field is 0.0016 to 80 μm². Thickness widths of the first layer are measured at three positions in one field, and an average value of the thickness widths at the three positions is specified as the thickness of the first layer.

### <Composition of First Unit Layer and Composition of Second Unit Layer>

The first unit layer is composed of Ti_{1-a-b}AlₐSc_{b}N, “a” represents 0.350 or more and 0.650 or less, and “b” represents 0.010 or more and 0.100 or less.

The “a” is 0.350 or more and 0.650 or less, may be 0.400 or more and 0.600 or less, or may be 0.450 or more and 0.550 or less.

The “b” is 0.010 or more and 0.100 or less, may be 0.020 or more and 0.090 or less, may be 0.030 or more and 0.080 or less, or may be 0.040 or more and 0.070 or less.

The phrase “the first unit layer is composed of Ti_{1-a-b}AlₐSc_{b}N” herein means that the first unit layer may contain an inevitable impurity in addition to Ti_{1-a-b}AlₐSc_{b}N as long as the effect of the present disclosure is not impaired. Examples of the inevitable impurity include oxygen, argon, and carbon. A content of the entire inevitable impurity in the first unit layer may be more than 0 atom % and less than 1 atom %.

The “a” and the “b” are determined by elemental analysis on the cross section of the flake of the coating using an energy dispersive X-ray spectrometer (EDX) attached to a transmission electron microscope (TEM) and measuring energy and generation times of characteristic X-ray generated in irradiation with electron beam. “c” in Al_{c}Cr_{1-c}N and “d” and “e” in Al_{d}Cr_{1-d-e}MₑN, described later, are measured by the same method.

The second unit layer is composed of Ti_{c}Si_{1-c}N, and “c” represents 0.20 or more and 0.99 or less. “c” may be 0.25 or more and 0.95 or less, or may be 0.30 or more and 0.90 or less.

The phrase “the second unit layer is composed of Ti_{c}Si_{1-c}N” herein means that the second unit layer may contain an inevitable impurity in addition to Ti_{c}Si_{1-c}N as long as the effect of the present disclosure is not impaired. Examples of the inevitable impurity include oxygen and carbon. A content of the entire inevitable impurity in the second unit layer may be more than 0 atom % and less than 1 atom %.

In the present disclosure, in the composition Ti_{1-a-b}AlₐSc_{b}N of the first unit layer, a ratio A_{N1}/A_{M1} of a number A_{N1} of atoms of N relative to a total number A_{M1} of atoms of Ti, Al, and Sc is 0.8 or more and 1.2 or less. In the present disclosure, in the composition Ti_{c}Si_{1-c}N of the second unit layer, a ratio A_{N2}/A_{M2} of a number A_{N2} of atoms of N relative to a total number A_{M2} of atoms of Ti and Si is 0.8 or more and 1.2 or less. The ratio A_{N1}/A_{M1} and the ratio A_{N2}/A_{M2} can be measured by a Rutherford backscattering (RBS) method. It has been confirmed that the effect of the present disclosure is not impaired when the ratio A_{N1}/A_{M1} and the ratio A_{N2}/A_{M2} are within the above ranges.

### <Average Thickness of First Unit Layers and Average Thickness of Second Unit Layers>

An average thickness of the first unit layers may be 2 nm or more and 200 nm or less, and an average thickness of the second unit layers may be 2 nm or more and 200 nm or less. The average thickness of the first unit layers may be 5 nm or more and 150 nm or less, or may be 10 nm or more and 100 nm or less. The average thickness of the second unit layers may be 5 nm or more and 150 nm or less, or may be 10 nm or more and 100 nm or less.

The average thickness of the first unit layers and the average thickness of the second unit layers are measured by the method same as the measurement method for the thickness of the first layer.

As illustrated in FIG. 5, between first unit layer 12 and second unit layer 15 adjacent to first unit layer 12, a ratio λ1/λ2 of a thickness λ1 (nm) of first unit layer 12 to a thickness λ2 (nm) of second unit layer 15 may be 1 or more and 5 or less, may be 1.1 or more and 5.0 or less, may be 1.2 or more and 5.0 or less, may be 1.3 or more and 4.0 or less, may be 1.8 or more and 3.0 or less, or 2.0 or more and 2.5 or less.

Although the thicknesses of all first unit layers 12 are represented as λ1 and the thicknesses of all second unit layers 15 are represented as λ2 in FIG. 5 for description, the thicknesses λ1 of all first unit layers 12 are not needed to be equal, and the thicknesses λ2 of all second unit layers 15 are not needed to be equal as long as the above relationship of λ1/λ2 is satisfied between the first unit layer and the second unit layer adjacent to each other.

In the first layer, the number of stacking of each of the first unit layers and the second unit layers may be 5 or more and 500 or less, may be 10 or more and 500 or less, may be 100 or more and 400 or less, or may be 200 or more and 350 or less. According to this, stacking of the first unit layers and the second unit layers can sufficiently yield the effect of improving the hardness, oxidation resistance, wear resistance, heat resistance, and chipping resistance of the first layer with good balance.

In the first layer, the number of stacking of each of the first unit layers and the second unit layers is measured by observing the flake sample of the cross section of the coating using a transmission electron microscope (TEM) with an observation magnification of 20,000 to 5,000,000. The number of stacking of each of first unit layers and third unit layers in an A layer, described later, is also measured by the same method.

### <Second Layer>

In the cutting tool of Embodiment 1, the coating may further include a second layer disposed between the base and the first layer. Composition of the second layer may be the same as the composition of any one unit layer of the first unit layer and the second unit layer. The second layer may be disposed directly on the base.

When the composition of the second layer is the same as the composition of the first unit layer, the passivated form composed of Sc₂O₃ is generated even when the second layer is exposed in initial cutting, and stability of performance of the cutting tool is improved. Further, the keying on effect of Sc₂O₃ can inhibit oxidation of the coating. Further, the keying on effect can inhibit reactivity between the workpiece and the coating, and can reduce the frictional coefficient between the workpiece and the coating.

When the composition of the second layer is the same as the composition of the first unit layer, the thickness of the second layer may be larger than the thickness of the first unit layer. This further improves stability of performance of the cutting tool due to formation of Sc₂O₃, the effect of inhibiting oxidation of the coating, and the effect of inhibiting reactivity between the workpiece and the coating. In addition, the frictional coefficient between the workpiece and the coating can be further reduced.

When the composition of the second layer is the same as the composition of the first unit layer, first unit layer 12 may be stacked directly on second layer 16, as illustrated in FIG. 3. As illustrated in FIG. 4, second unit layer 15 may be stacked directly on second layer 16. When the composition of the second layer is the same as the composition of the first unit layer and the first unit layer is stacked directly on the second layer, the second layer and the first unit layer have a continuous crystal structure.

When the composition of the second layer is the same as the composition of the second unit layer, the second unit layer tends to have a large compressive residual stress, and thereby breakage resistance of the coating can be improved particularly in intermittent processing, which repeatedly applies a load to the cutting edge.

The thickness of the second layer may be more than 1 time and 500 times or less, may be 2 times or more and 500 times or less, may be 4 times or more and 120 times or less, or may be 10 times or more and 50 times or less larger than the thickness of the unit layer that has the same composition.

The thickness of the second layer may be 0.1 μm or more and 2 μm or less, may be 0.3 μm or more and 2 μm or less, or 0.4 μm or more and 1 μm or less. This easily yields the above effect by disposing the second layer.

When the composition of the second layer is the same as the composition of the second unit layer, first unit layer 12 may be stacked directly on second layer 16, as illustrated in FIG. 3. As illustrated in FIG. 4, second unit layer 15 may be stacked directly on second layer 16. When the composition of the second layer is the same as the composition of the second unit layer and the second unit layer is stacked directly on the second layer, the second layer and the second unit layer have a continuous crystal structure.

### <Third Layer>

In the cutting tool of Embodiment 1, the coating may further include a third layer provided on a side opposite to the base of the first layer. The third layer may be disposed on the outermost surface of the coating. The third layer may be composed of TiCN or TiAlScCN.

When the third layer is composed of TiCN, regulating a composition ratio between N and C enables to impart a predetermined color. This can impart design properties and distinctive properties to appearance of the cutting tool, which yields commercial usefulness.

When the third layer is composed of TiAlScCN, the passivated form composed of Sc₂O₃ is generated under cutting conditions at high temperature to improve stability of performance of the cutting tool.

When the third layer is composed of TiAlScCN, a ratio of atoms of Ti, Al, and Sc in the third layer may be the same as a ratio of atoms of Ti, Al, and Sc in the first unit layer. Specifically, when the ratio of atoms of Ti, Al, and Sc in the first unit layer is Ti:Al:Sc=1-a-b:a:b, the ratio of atoms of Ti, Al, and Sc in the third layer may also be Ti:Al:Sc=1-a-b:a:b. This can produce the first unit layer and the third layer by using the same target when the coating is produced by a PVD method, which is advantageous in terms of a cost.

A thickness of the third layer may be 0.1 μm or more and 1.0 μm or less. When the thickness of the third layer is 0.1 μm or more, the above effect by disposing the third layer is good. With considering the cost aspect, the thickness of the third layer may be 1.0 μm or less. The thickness of the third layer may be 0.3 μm or more and 0.8 μm or less, or may be 0.5 μm or more and 0.6 μm or less.

### Embodiment 2: Cutting Tool (2)

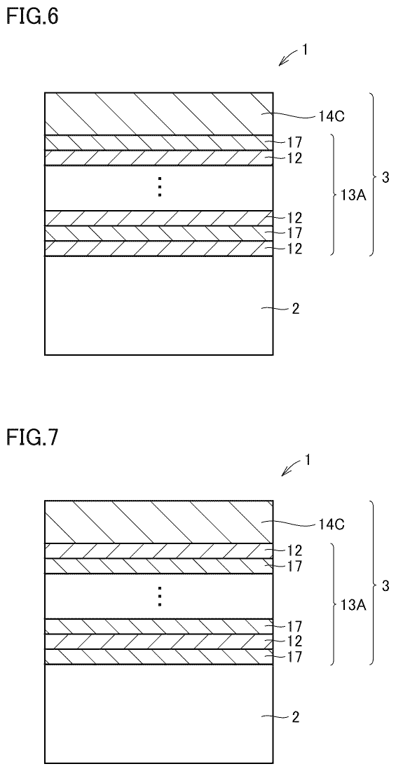

The cutting tool according to another embodiment of the present disclosure will be described by using FIG. 6 to FIG. 10. A cutting tool of Embodiment 2 is a cutting tool comprising: a base; and a coating disposed on the base. The coating includes an A layer. The A layer is composed of an alternate layer in which a first unit layer and a third unit layer are alternately stacked. The first unit layer is composed of Ti_{1-a-b}AlₐSc_{b}N. Here, “a” represents 0.350 or more and 0.650 or less, and “b” represents 0.010 or more and 0.100 or less. The third unit layer is composed of Ti_{d}Si_{1-d-e}BₑN. Here, “d” represents 0.20 or more and 0.99 or less, and “e” represents more than 0 and 0.05 or less.

The cutting tool of Embodiment 2 may have basically the same configuration as the cutting tool of Embodiment 1 except for configuration of the A layer, a B layer, and a C layer. Hereinafter, the points different from the cutting tool of Embodiment 1 will be described.

### <Coating>

As illustrated in FIG. 6 and FIG. 7, a coating 3 includes an A layer 13A, and A layer 13A may be provided directly on a base 2.

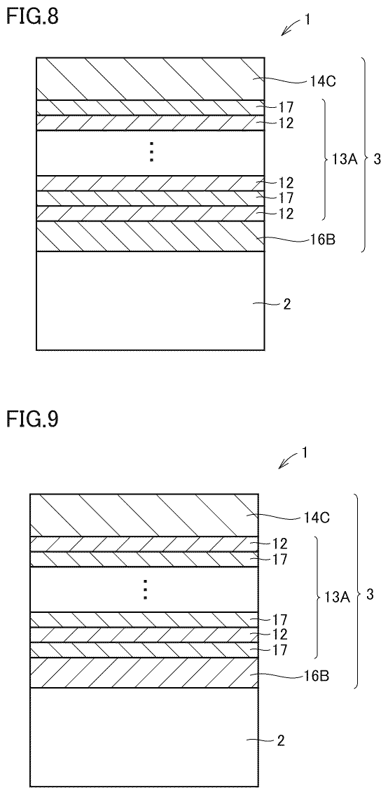

Coating 3 may include another layer in addition to A layer 13A. As illustrated in FIG. 8 to FIG. 9, coating 3 may include a B layer 16B disposed between base 2 and A layer 13A. As illustrated in FIG. 6 to FIG. 9, coating 3 may include a C layer 14C provided on a side opposite to base 2 of A layer 13A.

### <A Layer>

In the cutting tool of Embodiment 2, the A layer is composed of an alternate layer in which a first unit layer and a third unit layer are alternately stacked. A thickness of the A layer may be the same thickness of the first layer described in Embodiment 1. Any of the first unit layer and the third unit layer may be disposed at a position closest to the side of the base. The first unit layer may have a cubic crystal structure. The third unit layer may have a cubic crystal structure.

### <Composition of First Unit Layer and Composition of Third Unit Layer>

Composition Ti_{1-a-b}AlₐSc_{b}N of the first unit layer in Embodiment 2 may be the same as the composition Ti_{1-a-b}AlₐSc_{b}N of the first unit layer of Embodiment 1.

The third unit layer is composed of Ti_{d}Si_{1-d-e}BₑN, “d” represents 0.20 or more and 0.99 or less, and “e” represents more than 0 and 0.05 or less.

“d” is 0.20 or more and 0.99 or less. “d” may be 0.25 or more and 0.95 or less, or may be 0.30 or more and 0.90 or less.

“e” is more than 0 and 0.05 or less. This can improve hardness and oxidation resistance of the A layer. “e” may be 0.01 or more and 0.05 or less, may be 0.02 or more and 0.05 or less, may be 0.02 or more and 0.04 or less, or may be 0.02 or more and 0.03 or less.

The phrase “the third unit layer is composed of Ti_{d}Si_{1-d-e}BₑN” herein means that the third unit layer may contain an inevitable impurity in addition to Ti_{d}Si_{1-d-e}BₑN as long as the effect of the present disclosure is not impaired. Examples of the inevitable impurity include oxygen and carbon. A content of the entire inevitable impurity in the third unit layer may be more than 0 atom % and less than 1 atom %.

In the present disclosure, in the composition Ti_{d}Si_{1-d-e}BₑN of the third unit layer, a ratio A_{N3}/A_{M3} of a number A_{N3} of atoms of N relative to a total number A_{M3} of atoms of Ti, Si, and M is 0.8 or more and 1.2 or less. The ratio A_{N3}/A_{M3} can be measured by a Rutherford backscattering (RBS) method. It has been confirmed that the effect of the present disclosure is not impaired when the ratio A_{N1}/A_{M1} is 0.8 or more and 1.2 or less and the ratio A_{N3}/A_{M3} is within the above range.

### <Average Thickness of First Unit Layers and Average Thickness of Third Unit Layers>

An average thickness of the first unit layers may be 2 nm or more and 200 nm or less, and an average thickness of the third unit layers may be 2 nm or more and 200 nm or less. The average thickness of the first unit layers may be 5 nm or more and 150 nm or less, or may be 10 nm or more and 100 nm or less. The average thickness of the third unit layers may be 5 nm or more and 150 nm or less, or may be 10 nm or more and 100 nm or less.

The average thickness of the first unit layers and the average thickness of the third unit layers are measured by the method same as the measurement method for the thickness of the first layer.

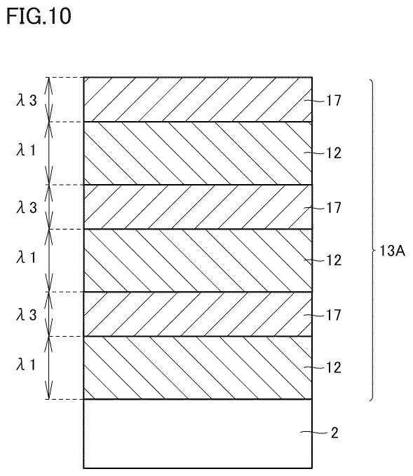

As illustrated in FIG. 10, between first unit layer 12 and third unit layer 17 adjacent to first unit layer 12, a ratio λ1/λ3 of a thickness λ1 (nm) of first unit layer 12 to a thickness λ3 (nm) of third unit layer 17 may be 1 or more and 5 or less, may be 1.1 or more and 5.0 or less, may be 1.2 or more and 5.0 or less, may be 1.3 or more and 4.0 or less, may be 1.8 or more and 3.0 or less, or 2.0 or more and 2.5 or less.

Although the thicknesses of all first unit layers 12 are represented as λ1 and the thicknesses of all third unit layers 17 are represented as λ3 in FIG. 10 for description, the thicknesses λ1 of all first unit layers 12 are not needed to be equal, and the thicknesses λ3 of all third unit layers 17 are not needed to be equal as long as the above relationship of 1/λ3 is satisfied between the first unit layer and the third unit layer adjacent to each other.

In the A layer, the number of stacking of each of the first unit layers and the third unit layers may be 5 or more and 500 or less, may be 10 or more and 500 or less, may be 100 or more and 400 or less, or may be 200 or more and 350 or less. According to this, stacking of the first unit layers and the third unit layers can sufficiently yield the effect of improving the hardness, oxidation resistance, wear resistance, heat resistance, and chipping resistance of the A layer with good balance.

### <B Layer>

In the cutting tool of Embodiment 2, the coating may further include a B layer disposed between the base and the A layer. Composition of the B layer may be the same as the composition of any one unit layer of the first unit layer and the third unit layer. The B layer may be disposed directly on the base.

The effect and a thickness of the B layer when the composition of the B layer is the same as the composition of the first unit layer are as described in Embodiment 1.

When the composition of the B layer is the same as the composition of the third unit layer, the second unit layer tends to have a large compressive residual stress, and thereby breakage resistance of the coating can be improved particularly in intermittent processing, which repeatedly applies a load to the cutting edge.

When the composition of the B layer is the same as the composition of the third unit layer, the thickness of the B layer may be larger than the thickness of the third unit layer. This can further improve breakage resistance of the coating.

The thickness of the B layer may be more than 1 time and 500 times or less, may be 2 times or more and 500 times or less, may be 4 times or more and 120 times or less, or may be 10 times or more and 50 times or less larger than the thickness of the third unit layer.

When the composition of the B layer is the same as the composition of the third unit layer, the thickness of the B layer may be 0.1 μm or more and 2 μm or less, may be 0.3 μm or more and 2 μm or less, or 0.4 μm or more and 1 μm or less. This easily yields the above effect by disposing the B layer.

When the composition of the B layer is the same as the composition of the third unit layer, first unit layer 12 may be stacked directly on a B layer 16B, as illustrated in FIG. 8. As illustrated in FIG. 9, third unit layer 17 may be stacked directly on B layer 16B. When the composition of the B layer is the same as the composition of the third unit layer and the third unit layer is stacked directly on the B layer, the B layer and the third unit layer have a continuous crystal structure.

### <C Layer>

The C layer may have the same configuration and effect as those of the third layer described in Embodiment 1.

### Embodiment 3: Method for Manufacturing Cutting Tool

In Embodiment 3, a method for manufacturing the cutting tool of Embodiment 1 or Embodiment 2 will be described. The method of Embodiment 3 for manufacturing the cutting tool comprises: a first step of preparing a base; and a second step of forming a coating on the base. The second step comprises forming a first layer or an A layer. Each step will be described in detail hereinafter.

### <First Step>

In the first step, the base is prepared. As the substrate, the base described in Embodiment 1 may be used. As the base, any bases conventionally known may be prepared.

### <Second Step>

In the second step, the coating is formed on the base. The second step comprises forming the first layer or the A layer.

In forming the first layer, the first unit layer and the second unit layer are alternately stacked by using a physical vapor deposition (PVD) method to form the first layer. In forming the A layer, the first unit layer and the third unit layer are alternately stacked by using a PVD method to form the A layer. To improve wear resistance of the coating that includes the first layer or the A layer, it is effective to form a layer composed of a compound that has high crystallinity. The present inventors have found that the layer composed of a compound that has high crystallinity can be formed and the coating has excellent wear resistance by using the physical vapor deposition method as the method for forming the first layer and the A layer.

As the PVD method, at least one selected from the group consisting of a cathode arc-ion plating method, a balanced magnetron sputtering method, an unbalanced magnetron sputtering method, and a high power impulse magnetron sputtering (HiPIMS) method may be used. A cathode arc-ion plating method that has a high ionization rate of raw material elements may be used. When the cathode arc-ion plating method is used, an ion bombardment treatment with metal for a surface of the base can be performed before the first layer or the A layer is formed. Thus, adhesiveness between the base and the coating that includes the first layer or the A layer is remarkably improved.

The cathode arc-ion plating method can be performed by: placing the base in an apparatus and placing a target as a cathode; then applying high voltage to the target for generating arc discharge to ionize and evaporate atoms that constitute the target; and depositing a substance on the base, for example.

The balanced magnetron sputtering method can be performed by: placing the base in an apparatus and placing a target on a magnetron electrode that has a magnet to form a balanced magnetic field; applying high-frequency electric power between the magnetron electrode and the base to generate gas plasma; and allowing gas ions generated by generation of this gas plasma to collide with the target; and depositing atoms released from the target on the base, for example.

The unbalanced magnetron sputtering method can be performed by setting the magnetic field generated by the magnetron electrode to be unbalanced in the aforementioned balanced magnetron spattering method, for example. The HiPIMS method, which can apply further higher voltage to obtain a dense film, may also be used.

### <Other Steps>

The second step may comprise, in addition to forming the first layer or the A layer, treating a surface of the coating, such as polishing using a brush and a dry or wet shot blasting. The second step may also comprise forming other layers such as a second layer, a third layer, a B layer, and a C layer. The other layers can be formed by a conventionally known chemical vapor deposition method or physical vapor deposition method. From the viewpoint of ability of forming the other layer continuously to the first layer or the A layer in one physical vapor deposition apparatus, the other layer is preferably formed by a physical vapor deposition method.

### EXAMPLES

The present embodiments will be further specifically described with Examples. However, the present embodiments are not limited by these Examples.

### Example 1

### <Sample 1 to Sample 18 and Sample 101 to Sample 109>

### <<Production of Cutting Tool>>

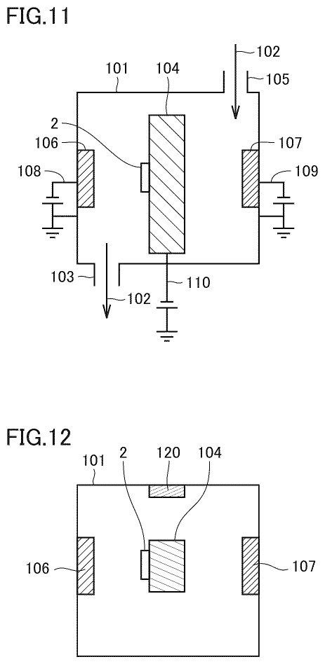

FIG. 11 is a schematic cross-sectional view of a cathode arc-ion plating apparatus used in Example 1. FIG. 12 is an outline top view of the apparatus in FIG. 11.

In the apparatus in FIG. 11 and FIG. 12, a cathode 106 for a first unit layer, a cathode 107 for a second unit layer, and a cathode 120 for a third layer, which are alloy targets serving as metal raw materials of a coating, and a rotary base holder 104 for placing the base are attached in a chamber 101. Cathode 106 is composed of Ti, Al, and Sc, and the ratio of each element is adjusted to obtain composition of the first unit layer in Table 1. Cathode 107 is composed of Ti and Si, and the ratio of each element is adjusted to obtain composition of the second unit layer in Table 1. Cathode 120 is composed of Ti.

An arc power source 108 is attached to cathode 106, an arc power source 109 is attached to cathode 107, and an arc power source (not illustrated) is attached to cathode 120. A bias power source 110 is attached to base holder 104. In chamber 101, a gas introducing port 105 to introduce gas 102 is provided and a gas discharging port 103 is provided for regulating a pressure in chamber 101, and chamber 101 has structure in which gas 102 in chamber 101 can be sucked by a vacuum pump through gas discharging port 103.

On base holder 104, a chip of a cemented carbide of JIS Standard K20 grade, SEMT13T3AGSN manufactured by Sumitomo Electric Hardmetal Corp., was attached as the base.

Then, a pressure in chamber 101 was reduced by the vacuum pump, and a temperature was raised to 600° C. by a heater placed in the apparatus while rotating the base, and evacuation was performed until the pressure in chamber 101 reached 1.0×10⁻⁴ Pa. Then, argon gas was introduced through the gas introducing port to hold the pressure in chamber 101 to be 2.0 Pa, a voltage of bias power source 110 was gradually raised to −1000 V, and cleaning of a surface of the substrate was performed for 15 minutes. Thereafter, the argon gas was discharged from chamber 101 to clean the base (argon bombard treatment). As above, the base of a cutting tool of each sample was prepared.

Then, in a state where the base was rotated at a center, arc current was supplied to cathodes 106 and 107 at each 120 A while introducing nitrogen as a reaction gas and holding a base temperature at 500° C., a reaction gas pressure at 2.0 Pa, a voltage of bias power source 110 at a predetermined constant value within a range of −50 V to −200 V to generate metal ions from cathodes 106 and 107, and the second layer that had composition shown in Table 2 and the first layer that had composition shown in Table 1 were formed on the base.

When the second layer was formed, the first layer was formed by alternately stacking each of the first unit layers and the second unit layers one by one on the second layer with the number of stacking shown in Table 1. When the second layer was not formed, the first layer was formed by alternately stacking each of the first unit layers and the second unit layers one by one on the base with the number of stacking shown in Table 1.

The thickness of the second layer and each thickness and the number of stacking of each of the first unit layers and the second unit layers in the first layer were regulated by a rotation speed of the base. At a time when the thicknesses of the second layer and the first layer reached the thicknesses respectively shown in Table 1 and Table 2, current supplied to the evaporation source was stopped. The description “-” in the column “Second layer” in Table 2 represents that the second layer is absent.

Then, while introducing nitrogen gas and methane gas as reaction gasses into chamber 101 and holding a base temperature at 400° C., a reaction gas pressure at 2.0 Pa, and a voltage of bias power source 110 at −300 V, arc current at 100 A was supplied to cathode 120 to generate metal ions from cathode 120, and a third layer was formed on the first layer. At a time when a thickness of the third layer reached a thickness shown in Table 2, current supplied to the evaporation source was stopped. As above, the cutting tool of each sample was produced. The description “-” in the column “Third layer” in Table 2 represents that the third layer is absent.

TABLE 1

| | First layer | | | | | | | |
|---|---|---|---|---|---|---|---|---|
| | First unit layer | | | Second unit layer | | | | |
| | (Ti_{1-a-b}AlₐSc_{b}N) | | | (Ti_{c}Si_{1-c}N) | | | Number | |
| Sample | | | Average | | Average | | of | Thickness |
| No. | a | b | thickness [nm] | c | thickness [nm] | λ1/λ2 | stacking | [μm] |
| 1 | 0.350 | 0.010 | 11 | 0.20 | 10 | 1.1 | 24 | 0.5 |
| 2 | 0.350 | 0.050 | 2 | 0.45 | 2 | 1.0 | 500 | 2.0 |
| 3 | 0.350 | 0.100 | 60 | 0.50 | 50 | 1.2 | 200 | 22.0 |
| 4 | 0.500 | 0.050 | 150 | 0.55 | 100 | 1.5 | 60 | 15.0 |
| 5 | 0.650 | 0.010 | 90 | 0.70 | 30 | 3.0 | 13 | 1.6 |
| 6 | 0.650 | 0.050 | 20 | 0.99 | 5 | 4.0 | 40 | 1.0 |
| 7 | 0.650 | 0.100 | 150 | 0.99 | 30 | 5.0 | 75 | 13.5 |
| 8 | 0.400 | 0.020 | 20 | 0.30 | 5 | 4.0 | 500 | 12.5 |
| 9 | 0.450 | 0.030 | 200 | 0.65 | 200 | 1.0 | 10 | 4.0 |
| 10 | 0.500 | 0.040 | 4 | 0.55 | 5 | 0.8 | 100 | 0.9 |
| 11 | 0.350 | 0.070 | 150 | 0.20 | 30 | 5.0 | 18 | 3.2 |
| 12 | 0.400 | 0.080 | 30 | 0.80 | 5 | 6.0 | 90 | 3.2 |
| 13 | 0.500 | 0.100 | 250 | 0.90 | 250 | 1.0 | 10 | 5.0 |
| 14 | 0.350 | 0.050 | 2 | 0.45 | 2 | 1.0 | 500 | 2.0 |
| 15 | 0.350 | 0.100 | 60 | 0.50 | 50 | 1.2 | 200 | 22.0 |
| 16 | 0.500 | 0.050 | 150 | 0.55 | 100 | 1.5 | 60 | 15.0 |
| 17 | 0.650 | 0.010 | 90 | 0.70 | 30 | 3.0 | 13 | 1.6 |
| 18 | 0.650 | 0.050 | 20 | 0.99 | 5 | 4.0 | 40 | 1.0 |
| 101 | 0.300 | 0.010 | 11 | 0.20 | 10 | 1.1 | 24 | 0.5 |
| 102 | 0.350 | 0.004 | 11 | 0.20 | 10 | 1.1 | 24 | 0.5 |
| 103 | 0.700 | 0.100 | 150 | 0.99 | 30 | 5.0 | 75 | 13.5 |
| 104 | 0.650 | 0.120 | 150 | 0.99 | 30 | 5.0 | 75 | 13.5 |
| 105 | 0.350 | 0.010 | 11 | 0.15 | 10 | 1.1 | 24 | 0.5 |
| 106 | 0.650 | 0.100 | 150 | 0.996 | 30 | 5.0 | 75 | 13.5 |
| 107 | 0.500 | 0.000 | 4 | 0.55 | 5 | 0.8 | 100 | 0.9 |
| 108 | 0.500 | 0.040 | 900 | — | — | — | 1 | 0.9 |
| 109 | — | — | — | 0.55 | 900 | — | 1 | 0.9 |

TABLE 2

| | Second layer | | Third layer | | Thickness | Cutting test 1 |
|---|---|---|---|---|---|---|
| Sample | | Thickness | | Thickness | of coating | Cut length |
| No. | Composition | [μm] | Composition | [μm] | [μm] | [km] |
| 1 | — | — | — | — | 0.5 | 5.5 |
| 2 | — | — | — | — | 2.0 | 6.3 |
| 3 | — | — | — | — | 22.0 | 5.1 |
| 4 | — | — | — | — | 15.0 | 7.2 |
| 5 | — | — | — | — | 1.6 | 6.0 |
| 6 | — | — | — | — | 1.0 | 5.8 |
| 7 | — | — | — | — | 13.5 | 7.5 |
| 8 | — | — | — | — | 12.5 | 7.3 |
| 9 | — | — | — | — | 4.0 | 6.8 |
| 10 | — | — | — | — | 0.9 | 5.6 |
| 11 | — | — | — | — | 3.2 | 6.5 |
| 12 | — | — | — | — | 3.2 | 6.4 |
| 13 | — | — | — | — | 5.0 | 7.0 |
| 14 | Same as first | 0.1 | — | — | 2.1 | 6.8 |
| | unit layer | | | | | |
| 15 | Same as second | 1.0 | — | — | 23.0 | 5.6 |
| | unit layer | | | | | |
| 16 | — | — | TiCN | 0.1 | 15.1 | 8.5 |
| 17 | — | — | TiAlScCN | 1.0 | 2.6 | 7.2 |
| 18 | Same as first | 1.0 | TiAlScCN | 0.1 | 2.1 | 7.0 |
| | unit layer | | | | | |
| 101 | — | — | — | — | 0.5 | 1.8 |
| 102 | — | — | — | — | 0.5 | 1.7 |
| 103 | — | — | — | — | 13.5 | 1.2 |
| 104 | — | — | — | — | 13.5 | 1.3 |
| 105 | — | — | — | — | 0.5 | 1.6 |
| 106 | — | — | — | — | 13.5 | 1.1 |
| 107 | — | — | — | — | 0.9 | 1.9 |
| 108 | — | — | — | — | 0.9 | 1.7 |
| 109 | — | — | — | — | 0.9 | 1.6 |

### <<Evaluation>>

On the cutting tool according to each sample, measured were: the composition of the first unit layer, the second unit layer, the second layer, and the third layer; the number of stacking of each of the first unit layers and the second unit layers; the average thickness of the first unit layers and the average thickness of the second unit layers; the thickness of the first layer, the thickness of the second layer, and the thickness of the third layer; and λ1/λ2 by the methods described in Embodiment 1. The results are shown in Table 1 and Table 2.

When “TiAlScCN” is described in the third layer, the ratio of atoms of Ti, Al, and Sc in the third layer was the same as the ratio of atoms of Ti, Al, and Sc in the first unit layer. The number of stacking of 10 represents that the alternate layer includes 10 first unit layers and 10 second unit layers. The description “-” in the column “λ1/λ2” means that at least any one of the first unit layer and the second unit layer is absent.

On the cutting tool of each sample of Sample 1 to Sample 18, the crystal structures of the first unit layer and the second unit layer were determined by XRD measurement on the first unit layer. The specific method was as described in Embodiment 1. On these samples, it was confirmed that the first unit layer had a cubic crystal structure and the second unit layer had a cubic crystal structure.

On the Sample 1 to Sample 18, hardness of the coating was measured by the method described in Embodiment 1. It was confirmed that the hardness of the coating of these samples was within a range of 30 GPa or more and 55 GPa or less.

On the Sample 1 to Sample 18, compressive residual stress of the coating was measured by the method described in Embodiment 1. It was confirmed that an absolute value of the compressive residual stress of the coating of these samples was 6 GPa or less.

### <Cutting Test 1: Milling Test>

With the cutting tool of each sample that had a SEMT13T3AGSN shape, surface milling was performed under the following cutting conditions by fitting: a center line of a plate with 150 mm in width; and a center of the cutter with Φ160 mm, which was wider than the plate, to measure a cut length until an amount of wear on a flank face of a cutting edge reached 0.2 mm. The results are shown in Table 2. A longer cut length indicates a longer tool lifetime.

### <<Cutting Conditions>>

Workpiece: FCD700 (HB250)
Cutting rate: 230 m/min
Feeding rate: 0.3 mm/t
Axial depth of cut “ap”: 2.0 mm
Radial depth of cut “ae”: 150 mm
Dry processing

The cutting processing performed under the above cutting conditions corresponds to cutting processing performed under conditions of high cutting-edge temperature.

The cutting tools of Sample 1 to Sample 18 correspond to Examples, and the cutting tools of Sample 101 to Sample 109 correspond to Comparative Examples. The cutting tools of Sample 1 to Sample 18 were confirmed to have a long tool lifetime compared with the cutting tools of Sample 101 to Sample 109 in the cutting processing performed under the conditions of high cutting-edge temperature.

### Example 2

### <Sample 21 to Sample 38 and Sample 121 to Sample 129>

A coating was formed on a base by using the cathode arc-ion plating apparatus same as in Example 1. Cathode 106 is composed of Ti, Al, and Sc, and the ratio of each element is adjusted to obtain composition of the first unit layer in Table 3 and Table 4. Cathode 107 is composed of Ti, Si, and B, and the ratio of each element is adjusted to obtain composition of the third unit layer in Table 3. Composition of cathode 120 is Ti.

On substrate holder 104, a chip of a cemented carbide of JIS Standard K20 grade, SEMT13T3AGSN manufactured by Sumitomo Electric Hardmetal Corp., was attached as the base, and the base was washed by the same method as in Example 1 to prepare the base.

Then, a B layer and C layer that had composition shown in Table 4 and an A layer that had composition shown in Table 3 were formed on the base under the same conditions as in Example 1 to obtain a cutting tool of each sample.

TABLE 3

| | A layer | | | | | | | | |
|---|---|---|---|---|---|---|---|---|---|
| | First unit layer | | | Third unit layer | | | | | |
| | (Ti_{1-a-b}AlₐSc_{b}N) | | | (Ti_{d}Si_{1-d-e}BₑN) | | | | | |
| | | | Average | | | Average | | Number | |
| Sample | | | thickness | | | thickness | | of | Thickness |
| No. | a | b | [nm] | d | e | [nm] | λ1/λ3 | stacking | [μm] |
| 21 | 0.350 | 0.010 | 11 | 0.20 | 0.01 | 10 | 1.1 | 24 | 0.5 |
| 22 | 0.350 | 0.050 | 2 | 0.30 | 0.02 | 2 | 1.0 | 500 | 2.0 |
| 23 | 0.350 | 0.100 | 60 | 0.40 | 0.03 | 50 | 1.2 | 200 | 22.0 |
| 24 | 0.500 | 0.050 | 150 | 0.50 | 0.04 | 100 | 1.5 | 60 | 15.0 |
| 25 | 0.650 | 0.010 | 90 | 0.70 | 0.05 | 30 | 3.0 | 13 | 1.6 |
| 26 | 0.650 | 0.050 | 20 | 0.99 | 0.01 | 5 | 4.0 | 40 | 1.0 |
| 27 | 0.650 | 0.100 | 150 | 0.99 | 0.02 | 30 | 5.0 | 75 | 13.5 |
| 28 | 0.400 | 0.020 | 20 | 0.90 | 0.03 | 5 | 4.0 | 500 | 12.5 |
| 29 | 0.450 | 0.030 | 200 | 0.30 | 0.04 | 200 | 1.0 | 10 | 4.0 |
| 30 | 0.500 | 0.040 | 4 | 0.55 | 0.05 | 5 | 0.8 | 100 | 0.9 |
| 31 | 0.350 | 0.070 | 150 | 0.20 | 0.05 | 30 | 5.0 | 18 | 3.2 |
| 32 | 0.400 | 0.080 | 30 | 0.80 | 0.03 | 5 | 6.0 | 90 | 3.2 |
| 33 | 0.500 | 0.100 | 250 | 0.60 | 0.01 | 250 | 1.0 | 10 | 5.0 |
| 34 | 0.350 | 0.050 | 2 | 0.30 | 0.02 | 2 | 1.0 | 500 | 2.0 |
| 35 | 0.350 | 0.100 | 60 | 0.40 | 0.03 | 50 | 1.2 | 200 | 22.0 |
| 36 | 0.500 | 0.050 | 150 | 0.50 | 0.04 | 100 | 1.5 | 60 | 15.0 |
| 37 | 0.650 | 0.010 | 90 | 0.70 | 0.05 | 30 | 3.0 | 13 | 1.6 |
| 38 | 0.650 | 0.050 | 20 | 0.99 | 0.01 | 5 | 4.0 | 40 | 1.0 |
| 121 | 0.300 | 0.010 | 11 | 0.20 | 0.01 | 10 | 1.1 | 24 | 0.5 |
| 122 | 0.350 | 0.004 | 11 | 0.20 | 0.01 | 10 | 1.1 | 24 | 0.5 |
| 123 | 0.700 | 0.100 | 150 | 0.99 | 0.02 | 30 | 5.0 | 75 | 13.5 |
| 124 | 0.650 | 0.120 | 150 | 0.99 | 0.02 | 30 | 5.0 | 75 | 13.5 |
| 125 | 0.350 | 0.010 | 11 | 0.15 | 0.01 | 10 | 1.1 | 24 | 0.5 |
| 126 | 0.650 | 0.100 | 150 | 0.995 | 0.02 | 30 | 5.0 | 75 | 13.5 |
| 127 | 0.500 | 0.000 | 4 | 0.55 | 0.05 | 5 | 0.8 | 100 | 0.9 |
| 128 | 0.500 | 0.040 | 900 | — | — | — | — | 1 | 0.9 |
| 129 | — | — | — | 0.55 | 0.05 | 900 | — | 1 | 0.9 |

TABLE 4

| | B layer | | C layer | | Thickness | Cutting test 2 |
|---|---|---|---|---|---|---|
| Sample | | Thickness | | Thickness | of coating | Cut length |
| No. | Composition | [μm] | Composition | [μm] | [μm] | [km] |
| 21 | — | — | — | — | 0.5 | 5.1 |
| 22 | — | — | — | — | 2.0 | 5.9 |
| 23 | — | — | — | — | 22.0 | 4.7 |
| 24 | — | — | — | — | 15.0 | 6.9 |
| 25 | — | — | — | — | 1.6 | 5.6 |
| 26 | — | — | — | — | 1.0 | 5.4 |
| 27 | — | — | — | — | 13.5 | 7.1 |
| 28 | — | — | — | — | 12.5 | 6.8 |
| 29 | — | — | — | — | 4.0 | 6.3 |
| 30 | — | — | — | — | 0.9 | 5.1 |
| 31 | — | — | — | — | 3.2 | 6.0 |
| 32 | — | — | — | — | 3.2 | 5.9 |
| 33 | — | — | — | — | 5.0 | 6.6 |
| 34 | Same as first | 0.1 | — | — | 2.1 | 6.4 |
| | unit layer | | | | | |
| 35 | Same as | 1.0 | — | — | 23.0 | 5.3 |
| | second unit | | | | | |
| | layer | | | | | |
| 36 | — | — | TiCN | 0.1 | 15.1 | 8.1 |
| 37 | — | — | TiAlScCN | 1.0 | 2.6 | 6.8 |
| 38 | Same as first | 1.0 | TiAlScCN | 0.1 | 2.1 | 6.6 |
| | unit layer | | | | | |
| 121 | — | — | — | — | 0.5 | 1.6 |
| 122 | — | — | — | — | 0.5 | 1.5 |
| 123 | — | — | — | — | 13.5 | 1.1 |
| 124 | — | — | — | — | 13.5 | 1.2 |
| 125 | — | — | — | — | 0.5 | 1.4 |
| 126 | — | — | — | — | 13.5 | 0.9 |
| 127 | — | — | — | — | 0.9 | 1.7 |
| 128 | — | — | — | — | 0.9 | 1.5 |
| 129 | — | — | — | — | 0.9 | 1.4 |

### <<Evaluation>>

On the cutting tool of each sample, measured were: the composition of the first unit layer, the third unit layer, the B layer, and the C layer, the number of stacking of each of the first unit layers and the third unit layers; the average thickness of the first unit layers and the average thickness of the third unit layers; the thickness of the A layer, the thickness of the B layer, and the thickness of the C layer; and λ1/λ3 by the same methods as in Example 1. The results are shown in Table 3 and Table 4.

On Sample 21 to Sample 38, it was confirmed that the first unit layer and the second unit layer had a cubic crystal structure. It was confirmed that hardness of the coating of Sample 21 to Sample 38 was within a range of 30 GPa or more and 55 GPa or less. It was confirmed that an absolute value of the compressive residual stress of the coating of Sample 21 to Sample 38 was 6 GPa or less.

### <Cutting Test 2: Milling Test>

With the cutting tool of each sample that had a SEMT13T3AGSN shape, surface milling was performed under the following cutting conditions by fitting: a center line of a plate with 150 mm in width; and a center of the cutter with Φ160 mm, which was wider than the plate, to measure a cut length until an amount of wear on a flank face of a cutting edge reached 0.2 mm. The results are shown in Table 4. A longer cut length indicates a longer tool lifetime.

### <<Cutting Conditions>>

Workpiece: SKD11 (HB250)
Cutting rate: 220 m/min
Feeding rate: 0.25 mm/t
Axial depth of cut “ap”: 2.0 mm
Radial depth of cut “ae”: 150 mm
Dry processing

The cutting processing performed under the above cutting conditions corresponds to cutting processing performed under conditions of high cutting-edge temperature.

The cutting tools of Sample 21 to Sample 38 correspond to Examples, and the cutting tools of Sample 121 to Sample 129 correspond to Comparative Examples. The cutting tools of Sample 21 to Sample 38 were confirmed to have a long tool lifetime compared with the cutting tools of Sample 121 to Sample 129 in the cutting processing performed under the conditions of high cutting-edge temperature.

The embodiments and Examples of the present disclosure have been described as above, but it is anticipated in advance that the aforementioned constitutions of embodiments and Examples are appropriately combined or variously modified.

The embodiments and Examples disclosed herein are examples in all points, and should not be limitative. The scope of the present invention is determined by not the above embodiments nor Examples but the claims, and intended to include meaning equivalent to the claims and all modification within the scope.

### REFERENCE SIGNS LIST

1 Cutting tool; 2 Base; 3 Coating; 12 First unit layer; 13 First layer; 13A A layer; 14 Third layer; 14C C layer; 15 Second unit layer; 16 Second layer; 16B B layer; 17 Third unit layer; 101 Chamber; 102 Gas; 103 Gas discharging port; 104 Base holder; 105 Gas introducing port; 106, 107, 120 Cathode; 108, 109 Arc power source; 110 Bias power source.

1. A cutting tool, comprising:
a base; and
a coating disposed on the base, wherein
the coating includes a first layer,
the first layer is composed of an alternate layer in which a first unit layer and a second unit layer are alternately stacked,
the first unit layer is composed of Ti_{1-a-b}AlₐSc_{b}N,
the a represents 0.350 or more and 0.650 or less,
the b represents 0.010 or more and 0.100 or less,
the second unit layer is composed of Ti_{c}Si_{1-c}N, and
the c represents 0.20 or more and 0.99 or less.

2. The cutting tool according to claim 1, wherein between the first unit layer and the second unit layer adjacent to the first unit layer, a ratio λ1/λ2 of a thickness λ1 of the first unit layer to a thickness λ2 of the second unit layer is 1 or more and 5 or less.

3. The cutting tool according to claim 1, wherein
an average thickness of the first unit layer is 2 nm or more and 200 nm or less, and
an average thickness of the second unit layer is 2 nm or more and 200 nm or less.

4. The cutting tool according to claim 1, wherein
the coating further includes a second layer disposed between the base and the first layer,
a composition of the second layer is same as a composition of any one unit layer of the first unit layer and the second unit layer,
a thickness of the second layer is larger than an average thickness of the unit layer that has the same composition, and
the thickness of the second layer is 0.1 μm or more and 1.0 μm or less.

5. The cutting tool according to claim 1, wherein
the coating further includes a third layer provided on a side opposite to the base of the first layer,
the third layer is composed of TiCN or TiAlScCN, and
a thickness of the third layer is 0.1 μm or more and 1.0 μm or less.

6. The cutting tool according to claim 1, wherein a thickness of the first layer is 0.5 μm or more and 15 μm or less.

7. A cutting tool, comprising:
a base; and
a coating disposed on the base, wherein
the coating includes an A layer,
the A layer is composed of an alternate layer in which a first unit layer and a third unit layer are alternately stacked,
the first unit layer is composed of Ti_{1-a-b}AlₐSc_{b}N,
the a represents 0.350 or more and 0.650 or less,
the b represents 0.010 or more and 0.100 or less,
the third unit layer is composed of Ti_{d}Si_{1-d-e}BₑN,
the d represents 0.20 or more and 0.99 or less, and
the e represents more than 0 and 0.05 or less.

8. The cutting tool according to claim 7, wherein between the first unit layer and the third unit layer adjacent to the first unit layer, a ratio λ1/λ3 of a thickness λ1 of the first unit layer to a thickness λ3 of the third unit layer is 1 or more and 5 or less.

9. The cutting tool according to claim 7, wherein
an average thickness of the first unit layer is 2 nm or more and 200 nm or less, and
an average thickness of the third unit layer is 2 nm or more and 200 nm or less.

10. The cutting tool according to claim 7, wherein
the coating further includes a B layer disposed between the base and the A layer,
a composition of the B layer is same as a composition of any one unit layer of the first unit layer and the third unit layer,
a thickness of the B layer is larger than an average thickness of the unit layer that has the same composition, and
the thickness of the B layer is 0.1 μm or more and 1 μm or less.

11. The cutting tool according to claim 7, wherein
the coating further includes a C layer provided on a side opposite to the base of the A layer,
the C layer is composed of TiCN or TiAlScCN, and
a thickness of the C layer is 0.1 μm or more and 1.0 μm or less.

12. The cutting tool according to claim 7, wherein a thickness of the A layer is 0.5 μm or more and 15 μm or less.
